(19) United States
(12) Patent Application Publication
(10) Pub. No.: US 2004/0037052 A1
(43) Pub. Date: Feb. 26, 2004

(54) Low-radiation mobile phone with two electromagnetic radiating sources

(76) Inventors: Yu-Yuan Wu, Taipei City (TW); Huang-Tse Peng, Hsi-Chih City (TW); Kai Shih, Taipei City (TW)

Correspondence Address: LADAS & PARRY, 224 SOUTH MICHIGAN AVENUE, SUITE 1200, CHICAGO, IL, 60604, US

(21) Appl. No.: 10/337,662

(22) Filed: Jan. 7, 2003

(30) Foreign Application Priority Data
Aug. 20, 2002 (TW) 091212938

(51) Int. Cl. H05K 5/00; H05K 5/04; H05K 5/06

(52) U.S. Cl. 361/752

(57) ABSTRACT

A low-radiation mobile phone includes an electrical circuit board, which is disposed within a housing and which includes a circuit board, an antenna in electrical connection with the circuit board for serving as one electromagnetic radiating source, and a conductive piece that has a grounding end in electrical connection with a grounding point of the circuit board, and a radiating end for serving as another electromagnetic radiating source. Because there are two electromagnetic radiating sources in the mobile phone, the Specific Absorption Rate of the mobile phone and thus the harmful effect of the electromagnetic radiation of the mobile phone on a human body can be reduced.

### CROSS REFERENCE TO RELATED APPLICATION

This application claims priority of Taiwanese Application No. 91212938, filed on Aug. 20, 2002.

### BACKGROUND OF THE INVENTION

1. Field of the Invention

This invention relates to a mobile phone, and more particularly to a low-radiation mobile phone, which includes two electromagnetic radiating sources provided for SAR (Specific Absorption Rate) reduction.

2. Description of the Related Art

Because mobile phones are convenient to use, almost everybody has one mobile phone. A conventional mobile phone is provided with an antenna that serves as an electromagnetic radiating source for electromagnetic radiation emission. It has been proved that the electromagnetic wave radiated from the antenna has a harmful effect on the human body. Especially, prolonged exposure to electromagnetic radiation is believed to cause certain diseases. The amount of electromagnetic waves to be absorbed into the human body per unit time is defined as SAR (Specific Absorption Rate). The accepted value of the SAR of mobile phones in use is below 1.6 mw/g, which meets the U.S. Federal Communications Commission (FCC) guidelines. Although the output power of a mobile phone can be reduced to decrease the value of the SAR, the quality of communication will be adversely affected. In order to minimize the harmful effect on the human body, it is required to reduce the SAR without negatively affecting the signal transmitting/receiving performance of the mobile phone.

### SUMMARY OF THE INVENTION

The object of this invention is to provide a low-radiation mobile phone which can reduce the harmful effect of electromagnetic radiation emitted therefrom on a human body.

Therefore, a low-radiation mobile phone of this invention includes a housing and an electrical circuit device installed within the housing. The electrical circuit device includes a circuit board having a grounding point, an antenna in electrical connection with the circuit board, and a conductive piece having a grounding end in electrical connection with the grounding point of the electrical circuit device, and a radiating end for electromagnetic radiation emission. The antenna and the radiating end of the conductive piece serve as two electromagnetic radiating sources, thereby reducing the Specific Absorption Rate of the mobile phone. As such, harmful effects of the mobile phone on a human body are diminished.

### BRIEF DESCRIPTION OF THE DRAWINGS

These and other features and advantages of this invention will become apparent in the following detailed description of a preferred embodiment of this invention, with reference to the accompanying drawings, in which:

FIG. 1 is a perspective view showing the preferred embodiment of a low-radiation mobile phone according to this invention, wherein a housing is shown in broken lines for illustrating clearly a circuit board, a liquid crystal display, an antenna, and a conductive piece;

FIG. 2 is a schematic side view showing the circuit board, the liquid crystal display, the antenna, and the conductive piece of the preferred embodiment;

FIG. 3 is a diagram illustrating the field intensity distribution of the electromagnetic radiation in the preferred embodiment when the conductive piece is removed; and

FIG. 4 is a diagram illustrating the field intensity distribution of the electromagnetic radiation in the preferred embodiment when the conductive piece is connected electrically to the circuit board.

### DETAILED DESCRIPTION OF THE PREFERRED EMBODIMENT

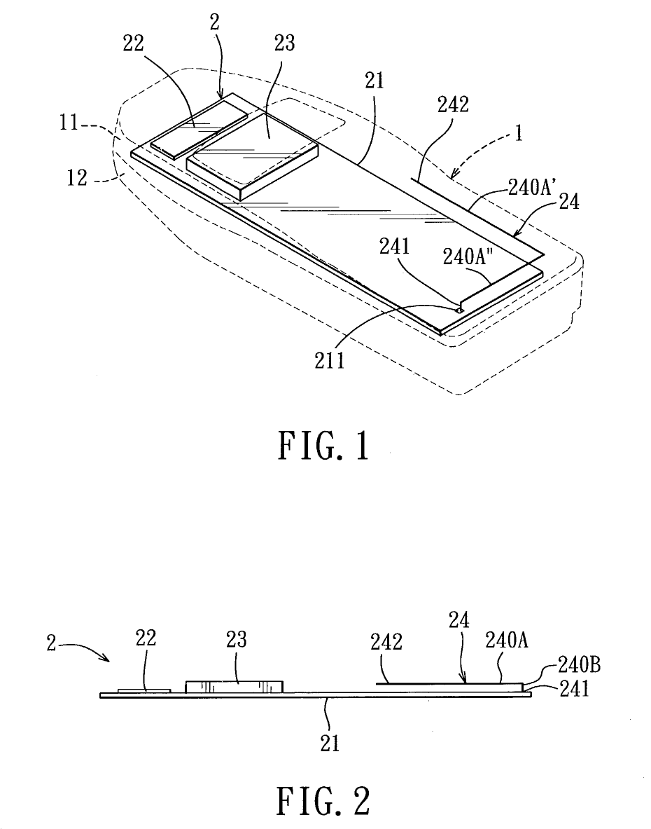

Referring to FIGS. 1 and 2, the preferred embodiment of a low-radiation mobile phone according to this invention is shown to include a housing 1 and an electrical circuit device 2. The housing 1 includes an upper housing 11 and a lower housing 12 that are interconnected fixedly and that define an accommodation chamber therebetween for receiving the electrical circuit device 2. The electrical circuit device 2 includes an elongated circuit board 21, an antenna 22 in electrical connection with the circuit board 21, and a liquid crystal display (LCD) 23 disposed on the circuit board 21 in a known manner.

This invention is different from the prior art in that the electrical circuit device 2 further includes a conductive piece 24 that is configured as a rigid metal wire, which has an L-shaped main wire portion (240A) and a connecting wire portion (240B) that extends integrally and perpendicularly from an end of the L-shaped main wire portion (240A). The L-shaped main wire portion (240A) extends in a plane parallel to the circuit board 21, and has a long section (240A′) extending along a longitudinal direction of the circuit board 21, and a short section (240A″) extending along a transverse direction of the circuit board 21.

The conductive piece 24 has a grounding end 241 in electrical connection with a grounding point 211 on the circuit board 21, and a radiating end 242 for electromagnetic radiation emission. The grounding end 241 is formed on the connecting wire portion (240B). The radiating end 242 is formed on the long section (240A′) of the L-shaped main wire portion (240A). The antenna 22 and the conductive piece 24 are connected respectively to the two ends of the circuit board 21. The grounding end 241 of the conductive piece 24 can be fixed to the grounding point 211 of the circuit board 21 by soldering. Alternatively, the L-shaped main wire portion (240A) of the conductive piece 24 is adhered to a planar inner surface (not shown) of the housing 1 along the overall length thereof such that the grounding end 241 of the conductive piece 24 presses against the grounding point 211 of the circuit board 21 so that the grounding end 241 of the conductive piece 24 is in electrical connection with the grounding point 211 of the circuit board 21.

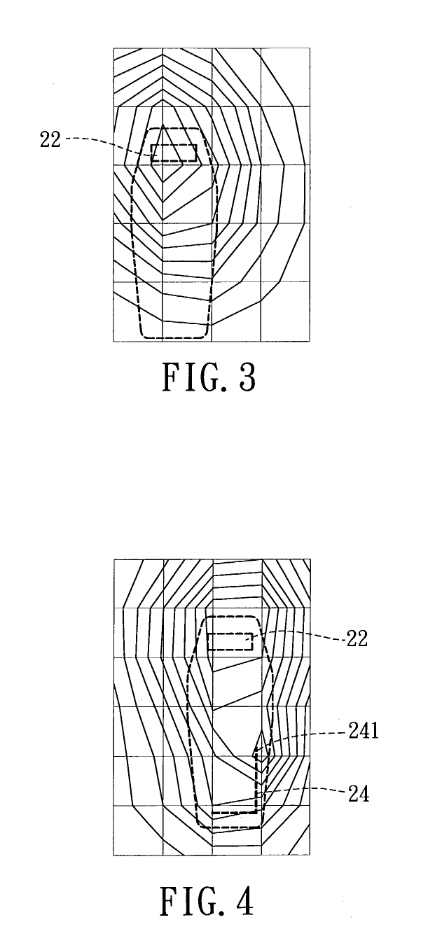

FIG. 3 is a diagram illustrating the field intensity distribution of the electromagnetic radiation produced by the mobile phone according to this invention when the conductive piece 24 (see FIG. 1) is removed from the circuit board 21 (see FIG. 1) so as to have a structure substantially similar to that of a conventional mobile phone, in which only the antenna 22 serves as the radiating source of electromagnetic waves (i.e. electromagnetic radiating source). As such, the value of the SAR of the mobile phone according to this invention is about 1.8 mw/g.

FIG. 4 is a diagram similar to FIG. 3 except that the grounding end 241 of the conductive piece 24 is connected electrically to the circuit board 21 (see FIG. 1) so that the antenna 22 and the radiating end 242 serve as two electromagnetic radiating sources. As such, the value of the SAR of the mobile phone is reduced to 1.2˜1.3 mw/g, thereby reducing significantly the harmful effect of electromagnetic radiation on the human body without adversely affecting the signal transmitting/receiving performance of the mobile phone.

With this invention thus explained, it is apparent that numerous modifications and variations can be made without departing from the scope and spirit of this invention. It is therefore intended that this invention be limited only as indicated by the appended claims.

We claim:

1. A low-radiation mobile phone comprising:
a housing; and
an electrical circuit device installed within said housing and including
a circuit board having a grounding point, and
an antenna in electrical connection with said circuit board, and
a conductive piece having a grounding end in electrical connection with said grounding point of said circuit board, and a radiating end for electromagnetic radiation emission, said antenna and said radiating end of said conductive piece serving as two electromagnetic radiating sources, thereby reducing Specific Absorption Rate of said mobile phone.

2. The low-radiation mobile phone as claimed in claim 1, wherein said conductive piece is configured as a metal wire.

3. The low-radiation mobile phone as claimed in claim 1, wherein said grounding end of said conductive piece is fixed to said grounding point of said circuit board by soldering.

4. The low-radiation mobile phone as claimed in claim 1, wherein said conductive piece is configured as a rigid metal wire, and has an L-shaped main wire portion that is adhered to said housing along overall length thereof and that is formed with said radiating end, and a connecting wire portion that extends integrally and perpendicularly from the other end of said L-shaped main wire portion and that is formed with said grounding end, said L-shaped main wire portion extending in a plane that is parallel to said circuit board, said grounding end of said conductive piece pressing against said grounding point of said circuit board so that said grounding end of said conductive piece is in electrical connection with said grounding point of said circuit board.
